(19) United States
(12) Patent Application Publication
(10) Pub. No.: US 2004/0057307 A1
(43) Pub. Date: Mar. 25, 2004

(54) Self-test circuit and a method for testing a memory with the self-test circuit

(76) Inventors: Dirk Fuhrmann, Munchen (DE); Peter Beer, Tutzing (DE); Martin Perner, Munchen (DE)

Correspondence Address: LERNER AND GREENBERG P.A., POST OFFICE BOX 2480, HOLLYWOOD, FL, 33022-2480, US

(21) Appl. No.: 10/667,254

(22) Filed: Sep. 19, 2003

(30) Foreign Application Priority Data
Sep. 19, 2002 (DE) 102 43 470.0

(51) Int. Cl. G11C 29/00

(52) U.S. Cl. 365/201

(57) ABSTRACT

A self-test circuit has an address generator unit for generating a test address for the purpose of testing a memory circuit and a control circuit that has signal inputs via which test commands can be applied and via which a memory access may be carried out. A first register is provided for storing an address difference value, in which case, as a result of a first test command, the address generator circuit increases the test address by the address difference value in the event of a subsequent memory access or, as a result of a second test command, the address generator circuit decreases the test address by the address difference value in the event of a subsequent memory access.

### BACKGROUND OF THE INVENTION

1. Field of the Invention

The invention relates to a self-test circuit that is integrated in an integrated circuit and is used for testing a memory circuit. The invention furthermore relates to a method for testing a memory circuit having a self-test circuit.

Integrated memory circuits are subjected to numerous test methods before they are ultimately delivered to the customer. A memory test involves checking whether an item of cell information that has been written to a cell can be retained and subsequently read out correctly. In the case of conventional test methods, the writing and subsequent reading-out operations are performed a number of times. Other memory operations which may result in the data stored in the relevant memory cell being changed are frequently performed between the writing and reading-out operations. A check is to be carried out in this case to ascertain whether storage is also affected in an error-free manner under certain conditions.

The process of repeatedly writing to, and reading out from, memory cells requires a great deal of time owing to the increasing storage density of memory circuits. Testing memory cells is therefore increasingly a cost factor that can be reduced by increasing the parallelism of the test system, that is to say the number of components that can be tested simultaneously.

One possibility of increasing the parallelism is to increase the number of test terminals on the tester unit. A further possibility is to reduce the number of requisite test lines between the component and the tester unit. This enables a greater number of integrated memory circuits to be tested in parallel using the test system.

In order to increase the throughput of the memory test further, some of the test system functionality is frequently transferred, in the form of a self-test unit, from the tester unit to the integrated circuit to be tested.

A self-test unit of this type undertakes, for example, the generation of test addresses. The self-test unit usually has minimal functionality owing to area limitations and is characterized in that, following initialization, the address space is passed through by incremental or decremental address generation with a step size of 1. The particular address generation operations that are required for certain special memory tests are implemented by additional address interchanging circuits.

With a reduced number of external terminals, a self-test unit of this type is restricted to the extent that only the address step size of 1 is possible in only one incrementation direction, in which case addressing may be effected either in the X direction or in the Y direction. A possibility of jumping is not usually provided within the address space. The self-test unit may be configured only once and cannot be controlled further during testing.

### SUMMARY OF THE INVENTION

It is accordingly an object of the invention to provide a self-test circuit and a method for testing a memory with the self-test circuit that overcome the above-mentioned disadvantages of the prior art devices and methods of this general type, which can be used to test a memory circuit in a more flexible and comprehensive manner.

With the foregoing and other objects in view there is provided, in accordance with the invention, a self-test circuit. The self-test circuit contains an address generator circuit for generating a test address for testing a memory circuit, and a control circuit connected to the address generator circuit for controlling the address generator circuit. The control circuit has signal inputs for receiving test commands. A register stores an address difference value and is connected to the control circuit and to the address generator circuit. Upon receiving a first test command the control circuit drives the address generator circuit to increase the test address by the address difference value in an event of a subsequent memory access. Upon receiving a second test command the control circuit drives the address generator circuit to decrease the test address by the address difference value in an event of the subsequent memory access.

A first aspect of the present invention provides a self-test circuit having an address generator unit for generating a test address for the purpose of testing a memory circuit. The address generator circuit is connected to a control circuit for controlling the address generator circuit, the control circuit having signal inputs via which test commands can be applied.

A first register is provided for the purpose of storing an address difference value. The control circuit drives the address generator circuit in such a manner that, as a result of a first test command, the test address is increased by the address difference value in the event of a subsequent memory access or, as a result of a second test command, the test address is decreased by the address difference value in the event of a subsequent memory access.

The self-test circuit according to the invention has the advantage that an address difference value can be stored in the first register, the value enabling the test address to be increased by address values other than 1. Whereas customary self-test units according to the prior art only allow the address to be increased or decreased by 1, it is possible, according to the invention, to also perform other jumps in accordance with the address difference value that can be stored in the first register. However, it is also possible, during the test method, to alter the address difference value stored in the first register, with the result that different address jumps may be realized.

Provision is preferably made for it to be possible to write the address difference value to the first register with the aid of a programming command that is applied to the control circuit. An external tester unit may thus define an address difference value that is to be used to test the memory circuit.

Provision is preferably made for the self-test circuit to contain a second register for the purpose of storing a second address difference value. The second address difference value may be written to the second register with the aid of a second programming command, for example. The control circuit drives the address generator circuit in such a manner that, as a result of a third test command, the test address is increased by the second address difference value in the event of a subsequent memory access or, as a result of a fourth test command, the test address is decreased by the second address difference value in the event of a subsequent memory access.

The provision of two registers for storing two address difference values considerably increases the flexibility of the address generation operation which is to be performed by the self-test circuit since it is now possible to jump flexibly in the address space to be tested using two different address difference values.

The first, second, third and fourth test commands are preferably coded in such a way that the memory circuit is essentially not addressed for reading or writing. The no-operation command (NOP command) is preferably used for this purpose, in which case the test commands can be coded using additional signals such as, for example, the circuit select signal or address bit signals that are not required. This makes it possible to apply the test commands without having to provide additional external terminals.

The address generator unit preferably has an adder unit and a subtractor unit, each of which can be activated depending on the test commands. The adder unit and the subtractor unit are respectively connected to the first and the second register in such a manner that the address difference values written to the first and the second register, respectively, can be added to, or subtracted from, the respective current test address.

A further aspect of the present invention provides a method for testing a memory circuit having a self-test circuit that has a first register for storing an address difference value. The address difference value is written to the first register, in which case, as a result of a first test command, the test address is increased by the address difference value in the event of a subsequent memory access and, as a result of a second test command, the test address is decreased by the address difference value in the event of a subsequent memory access. The first test command and the second test command are preferably applied successively to the control circuit in order to jump back and forth between two test addresses. A test method that frequently occurs when testing a memory circuit can be implemented in this way, the method testing the extent to which two memory addresses influence one another during repeated memory accesses.

Provision may also be made for the test method to be implemented using a self-test circuit having the first register for storing a first address difference value and having a second register for storing a second address difference value, it being possible to write different address difference values to the two registers. As a result of the first test command, the test address is increased by the first address difference value and, as a result of a second test command, it is decreased by the first address difference value. A second address difference value is written to the second register, in which case, as a result of the third test command, the test address is increased by the second address difference value and, as a result of a fourth command, the test address is decreased by the second address difference value.

Provision is preferably made for the first command, the third command, the fourth command and the second command to be applied successively to the control circuit in order to jump back and forth between four test addresses.

Furthermore, a start command can be applied to the self-test circuit to start the testing of the memory circuit by the self-test circuit.

Other features which are considered as characteristic for the invention are set forth in the appended claims.

Although the invention is illustrated and described herein as embodied in a self-test circuit and a method for testing a memory with the self-test circuit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block diagram of a self-test circuit according to the invention; and

FIG. 2 is a table containing a preferred coding scheme for test commands of the self-test circuit according to the invention.

### DESCRIPTION OF THE PREFERRED EMBODIMENTS

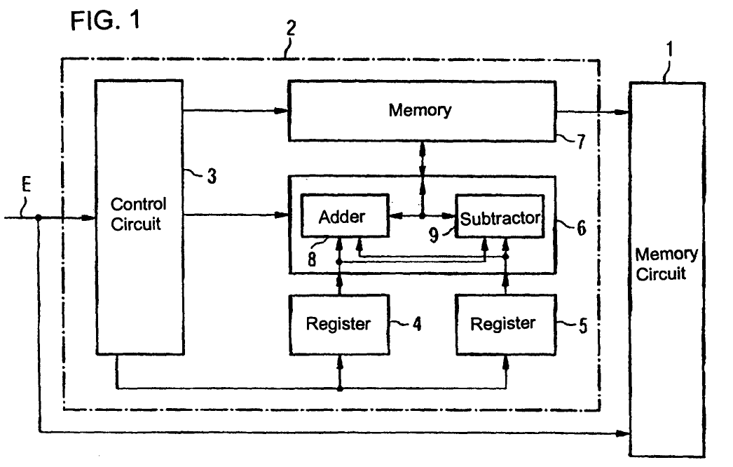

Referring now to the figures of the drawing in detail and first, particularly, to FIG. 1 thereof, there is shown a block diagram of an integrated memory module. The memory module has a memory circuit 1 and a self-test circuit 2. The self-test circuit 2 essentially generates test addresses, test data being intended to be written to the memory areas in the memory circuit 1 that are addressed by the test addresses. The memory circuit 1 is a DRAM memory circuit but any other desired memory circuit such as, for example, an SRAM memory circuit or the like may also be provided.

The memory circuit 1 and the self-test circuit 2 are connected to external terminals via which input signals E can be applied. In the case of DRAM memories, the input signals are usually a clock signal CLK, a word line activation signal RAS, a bit line activation signal CAS, a write signal WE, a circuit select signal CS, address signals A, data signals DQ and possibly others.

The word line activation signal RAS serves to activate a word line in the memory circuit, with the result that the memory transistors located thereon are turned on and charges of storage capacitances connected thereto flow onto the corresponding bit lines. Following activation of the word line and after the charges which have flowed onto the bit line have been amplified, the bit line activation signal CAS serves to select those bit lines whose stored data are to be applied to the data outputs. The write signal WE serves to signal whether the activation of the word line or the activation of the bit line is being carried out in order to perform a write access or a read access. The memory module in question is selected with the aid of the circuit select signal CS. The circuit select signal CS is required when a plurality of memory modules are connected to an external signal bus so that the circuit select signal CS can be used to define that memory module for which the signals applied on the signal bus are intended to be valid.

The self-test circuit 2 has a control circuit 3 that receives the input signals E. The control circuit 3 is configured in such a manner that it is capable of detecting the test commands which relate to the self-test circuit 2 and are applied by the input signals. In addition, one or more non-illustrated mode-set registers (MSR) are frequently provided in the control circuit, it being possible to store test parameters in the registers.

The control circuit 3 is connected to a first register 4 and a second register 5, it being possible to write to the first register 4 and the second register 5 by suitable test commands which are applied to the control circuit 3 via the signal inputs E. The first register 4 and the second register 5 store address difference values that specify desired address jumps in the test address during subsequent testing.

The control circuit 3 is connected to an address generator circuit 6 and to an address holding memory 7. The address holding memory 7 stores an address value that is provided for addressing a memory area in the memory circuit 1. During testing, the address generator circuit 6 alters the respectively current test address stored in the address holding memory 7 by one of the address difference values stored in the first register 4 or in the second register 5. A test command, which is applied at the signal input of the control circuit 3 and of which the address generator circuit is informed by the control circuit 3, determines whether the test address is to be increased or decreased by the respective address difference value.

There is thus a first test command which provides for the address difference value in the first register 4 to be added to the test address stored in the address holding memory 7, a second test command which provides for the address difference value in the first register to be subtracted from the test address, a third test command which provides for the address difference value in the second register 5 to be added to the test address, and a fourth test command which provides for the address difference value in the second register 5 to be subtracted from the test address.

After one of the test commands has been applied, each subsequent word line activation signal RAS causes the computation operation prescribed by the corresponding test command to be performed with respect to the test address. If, for example, an address difference value of 3 has been stored in the second register and a fourth test command has been applied, the test address stored in the address holding memory 7 is decreased by 3 for each subsequent activated word line activation signal RAS.

In order to store the computation operation prescribed by the respective test command, a non-illustrated state memory may be provided in the address generator circuit 6, which state memory indicates the operation to be performed on the test address when a word line activation signal RAS is activated.

The address generator unit 6 has an adder unit 8 and a subtractor unit 9 for the purpose of addition and subtraction. The respectively current test address and the address difference values in the first register 4 and in the second register 5 may be applied both to the adder unit 8 and to the subtractor unit 9.

In order to dispense with having to provide additional input signal terminals for the self-test circuit 2 according to the invention, provision is made for the corresponding test commands to be coded using the input signal terminals that already exist. For this purpose, in the case of an NOP command, which normally does not effect an operation in the memory circuit addressed in this way, provision is preferably made for carrying out additional coding using the address inputs of the memory module.

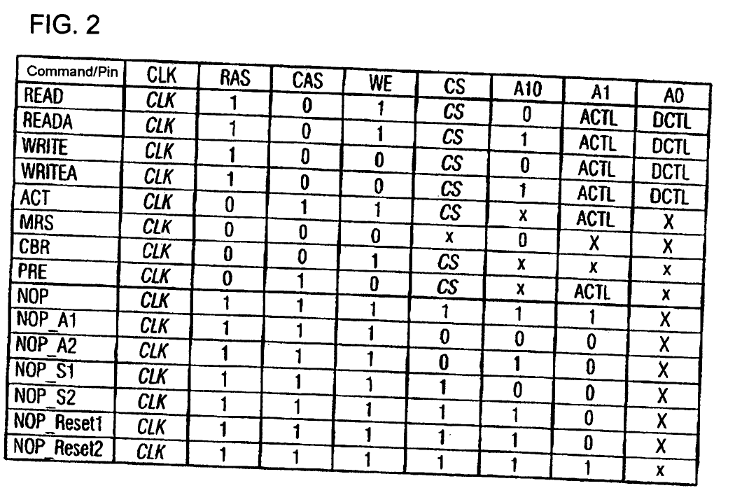

The table in FIG. 2 illustrates conventional coding of the signal inputs using the first eight commands, it being possible to apply read commands READ and write commands WRITE, word line activation commands ACT, mode register set commands (MRS), auto-refresh commands CBR, and precharge commands PRE to the memory module by the above-mentioned signal inputs E. The control signals applied are usually active low signals, that is to say they affect a function when their signal level changes from a high state to a low state. If the word line activation signal RAS, the bit line activation signal CAS and the write signal WE are deactivated, that is to say are in a high state, with the result that the circuit driven in this manner would usually not execute a command, additional commands may be coded using the circuit select signal and some or all of the address inputs.

This is shown in the table in FIG. 2, in which six further commands relating to the self-test circuit according to the invention are coded by address signals applied to the address inputs. The first test command is designated NOP_A1, the second test command is designated NOP_S1, the third test command is designated NOP_A2 and the fourth test command is designated NOP_S2. In addition to these four test commands, a fifth test command NOP_Reset1, which causes an address difference value of 1 to be written to the first register 4, and a sixth test command NOP_Reset2, which likewise causes an address difference value of 1 to be written to the second register 5, are provided. This constitutes a resetting of the contents of the registers 4, 5, with the result that the self-test circuit operates in the manner of a conventional self-test circuit and respectively increments or decrements the test address value by 1.

The first and the second register and also the register in the control unit 3 are initialized by the command MRS in which the word line activation signal RAS, bit line activation signal CAS and write signal WE have been activated, that is to say have been changed to a low state. The relevant register and the contents of the selected register are selected by one or more address or data bits which are to be set. The registers 4, 5 may possibly each be occupied by an address difference value by further subsequent mode register set commands. This may take place serially or in parallel depending on the number of address inputs that are to be used for transferring the address difference values into the registers 4, 5. The address width of the first register 4 and of the second register 5 may be adapted to the cell array which is to be addressed, the bit width of the registers 4, 5 primarily being determined by the maximum address difference value to be used.

Following writing to the registers 4, 5, test commands that serve to implement the test method for the memory component may be applied by the tester unit via the external test terminals. Since only a limited number of external terminals are available, specific coding of the commands for address calculation is required.

When in the high state, the address control bit denoted ACTL in the table in FIG. 2 prevents the test address from being incremented as a result of a word line activation command ACT, a read command READ and a write command WRITE. The data control bit DCTL causes the test datum that is to be written or read out to be inverted in the high state.

The above-mentioned test commands, with the aid of the NOP command and with additional use of one or more further address inputs, are used to code the commands for test address calculation.

The invention thus involves providing the self-test unit 2 that has the control unit 3, the functionality of the self-test circuit 2 being extended by additional coding without having to increase the number of external terminals on the memory module. The provision of two additional registers for storing address difference values allows the functionality to be considerably extended when calculating test addresses. A self-test circuit 2 of this type nevertheless still requires less area than the address interchanging circuits that are usually provided.

One particular feature of memory modules is, in many cases, the presence of a redundant memory area that is used for repairing defective memory cells. The redundant memory area either has its own separate address area or is divided into smaller areas in the form of address segments. A general problem when generating addresses is ascertaining whether the test address is addressing precisely the main memory area or whether it is located in one of said address redundancy areas.

In order to generate test addresses for addressing the redundant memory area, either a jump address may be loaded which causes the test address to jump immediately to the start of the redundancy area in the event of a subsequent memory access, or a changeover to the redundant memory area may be effected via a test mode which is determined externally by a command which is prescribed by the tester unit. According to the invention, it is also possible for a non-illustrated address overflow circuit to be provided, in which case, in the event of an address overflow or underflow, counting is not continued at the end or start of the normal memory area, but rather a jump is made to a test address in the redundant memory area.

It goes without saying that an address overflow circuit may also be provided which causes the address to be reset when the limit of the address space is reached. An address comparison logic unit may be initialized, for example, via a mode register set command in order to ensure that the addresses are reset after address overflows. That is to say, when an increase in the test address by the address difference value or a decrease in the test address by the address difference value does not bring about a jump to the exact start address or the exact end address of the address space, resetting to the exact start or the exact end of the address space is performed. Jumps of this kind into the interior of the address space may occur when the address difference value is not equal to 1.

Possible address space passes are presented below. The test command NOP-RESET1 is first applied for a normal pass through the cell array in the forward direction using the step size 1, as a result of which the address difference value in the first register is set to the step size 1 and the adder is activated. Each further activation of the word lines by the RAS signal or the ACT command, respectively, increments the X address by this step size and each further write or read command increments the Y address by this step size. With the aid of the NOP-Reset2 command, the step size in the second register 5 is set to the address difference value 1 and the subtractor is activated. Each further ACT command decreases the X address by the step size 1 and each further write or read command decreases the Y address by the step size 1.

If a cell array is to be passed through forward in the X direction using a step size of 4 and in the Y direction using a step size of 1, a mode register set command is first used to transfer the address difference value 4 to the first register 4. The command NOP_A1 is used to set the address generator unit 6 in such a manner that the adder is activated in order to add the address difference value of 4 stored in the first register 4 to the current test address. Each further ACT command increments the X address by the step size 4. After the X address has been incremented by the step size 4, a NOP_Reset1 command is applied which resets the address step size in the first register to 1. The Y address is then incremented by the step size 1 in the event of subsequent read or write commands.

In the case of cell array passes in which a jump is made back and forth between various X addresses, for example using the following sequence: address+1, address+3, address−3, address−1, mode register set commands are first of all used to transfer the value 1 to the first register 4 and the value 3 to the second register 5. The test command NOP_A1 is used to activate the test generator circuit 6 in order to activate the adder 8, which increases the x address by the address difference value stored in the first register 4 in the event of a subsequent word line activation signal RAS or ACT command, respectively. An NOP_A2 command is subsequently applied, with the result that the x address is increased by the address difference value 3 stored in the second register 5 in the event of a subsequent word line activation signal RAS. The subtractor unit 9 is subsequently activated by an NOP_S2 command, with the result that the x address is decreased by the address difference value in the second register 5 in the event of a subsequent word line activation signal RAS. The NOP_S1 command activates the subtractor unit 9 in the address generator circuit 6, with the result that the x address is decreased by the address difference value in the first register 4 in the event of a subsequent word line activation signal RAS. If the value is to be reset to 1 again for the purpose of generating y addresses, an NOP_Reset1 command or NOP_Reset2 command, respectively, must be applied in the command sequence between each word line activation signal RAS or the ACT command, respectively, and a read/write command.

We claim:

1. A self-test circuit, comprising:
an address generator circuit for generating a test address for testing a memory circuit;
a control circuit connected to said address generator circuit for controlling said address generator circuit, said control circuit having signal inputs for receiving test commands; and
a register storing an address difference value and connected to said control circuit and to said address generator circuit, upon receiving a first test command said control circuit driving said address generator circuit to increase the test address by the address difference value in an event of a subsequent memory access, upon receiving a second test command said control circuit driving said address generator circuit to decrease the test address by the address difference value in an event of the subsequent memory access.

2. The self-test circuit according to claim 1, wherein said control circuit writes the address difference value to said first register with an aid of a programming command.

3. The self-test circuit according to claim 1, further comprising:
a further register storing a further address difference value and connected to said control circuit and to said address generator circuit, upon receiving a third test command said control circuit driving said address generator circuit to increase the test address by the further address difference value in an event of the subsequent memory access, upon receiving a fourth test command said control circuit driving said address generator circuit to decrease the test address by the further address difference value in an event of the subsequent memory access.

4. The self-test circuit according to claim 3, wherein said control circuit writes the further address difference value to said further register with an aid of a further programming command.

5. The self-test circuit according to claim 1, wherein said address generator unit has an adder unit and a subtractor unit, each of which can be activated depending on the test commands.

6. The self-test circuit according to claim 1, wherein said control circuit starts a generation of the test address by said address generator unit in dependence on a start command.

7. A method for testing a memory circuit having a self-test circuit, which comprises the steps of:
writing an address difference value to a first register;
increasing a test address by the address difference value in an event of a subsequent memory access upon receiving a first test command; and
decreasing the test address by the address difference value in an event of the subsequent memory access upon receiving a second test command.

8. The method according to claim 7, which further comprises applying the first test command and the second test command successively to jump back and forth between two test addresses.

9. The method according to claim 7, which further comprises applying a start command to the self-test circuit to start testing of the memory circuit by the self-test circuit.

10. A method for testing a memory circuit having a self-test circuit, which comprises the steps of:
writing a first address difference value to a first register;
increasing a test address by the first address difference value in an event of a subsequent memory access upon receiving a first test command;
decreasing the test address by the first address difference value in an event of the subsequent memory access upon receiving a second test command;
writing a second address difference value to a second register;
increasing the test address by the second address difference value in an event of the subsequent memory access upon receiving a third test command; and
decreasing the test address by the second address difference value in an event of the subsequent memory access upon receiving a fourth test command.

11. The method according to claim 10, which further comprises applying the first test command, the third test command, the fourth test command and the second test command successively to jump back and forth between the four test addresses.

12. The method according to claim 10, which further comprises applying a start command to the self-test circuit to start testing of the memory circuit by the self-test circuit.
